(19) United States
(12) Patent Application Publication
(10) Pub. No.: US 2025/0364015 A1
(43) Pub. Date: Nov. 27, 2025

(54) Memory Circuitry And Methods Used In Forming Memory Circuitry

(71) Applicant: Micron Technology, Inc., Boise, ID (US)

(72) Inventors: Chia Ying Lin, Taichung City (TW); Vivek Yadav, Meridian, ID (US); Jerome A. Imonigie, Meridian, ID (US); Efe S. Ege, Boise, ID (US); Russell A. Benson, Boise, ID (US); Brendan Gunning, Boise, ID (US)

(73) Assignee: Micron Technology, Inc., Boise, ID (US)

(21) Appl. No.: 19/184,199

(22) Filed: Apr. 21, 2025

Related U.S. Application Data
(60) Provisional application No. 63/650,232, filed on May 21, 2024.

(51) Int. Cl. G11C 5/06; H10B 12/00

(52) U.S. Cl. CPC G11C 5/063; H10B 12/0335; H10B 12/05; H10B 12/09; H10B 12/315; H10B 12/482; H10B 12/50

(57) ABSTRACT

Memory circuitry comprises transistors individually comprising one and another source/drain regions, a channel region there-between, and a gate operatively proximate the channel region. Conductive vias are individually directly above and electrically coupled to individual of the another source/drain regions and are individually in a cavity that is in insulating material that is laterally over sides of the one source/drain regions of multiple of the transistors. Insulative material is in the cavity circumferentially around the individual conductive via and comprises SiOₓC_{y}, where “x” is 0.46 to 1.8 and “y” is 0.01 to 1.1. At least a majority of the insulative material in the cavity is being the SiOₓC_{y}. Digitlines are individually directly electrically coupled to a plurality of the conductive vias along a line of a plurality of the transistors. Storage elements are individually electrically coupled to individual of the one source/drain regions. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. The polarization state of the ferroelectric material can be changed by application of suitable programming voltages and remains after removal of the programming voltage (at least for a time). Each polarization state has a different charge-stored capacitance from the other, and which ideally can be used to write (i.e., store) and read a memory state without reversing the polarization state until such is desired to be reversed. Less desirable, in some memory having ferroelectric capacitors the act of reading the memory state can reverse the polarization. Accordingly, upon determining the polarization state, a re-write of the memory cell is conducted to put the memory cell into the pre-read state immediately after its determination. Regardless, a memory cell incorporating a ferroelectric capacitor ideally is non-volatile due to the bi-stable characteristics of the ferroelectric material that forms a part of the capacitor. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIGS. 1-10 are diagrammatic cross-sectional views of a portion of a DRAM construction in fabrication in accordance with some embodiments of the invention.

FIGS. 11-21 are diagrammatic sequential sectional views of the construction of FIGS. 1-10 in subsequent processing, or alternate embodiments, in accordance with some embodiments of the invention.

### DETAILED DESCRIPTION OF EXAMPLE EMBODIMENTS

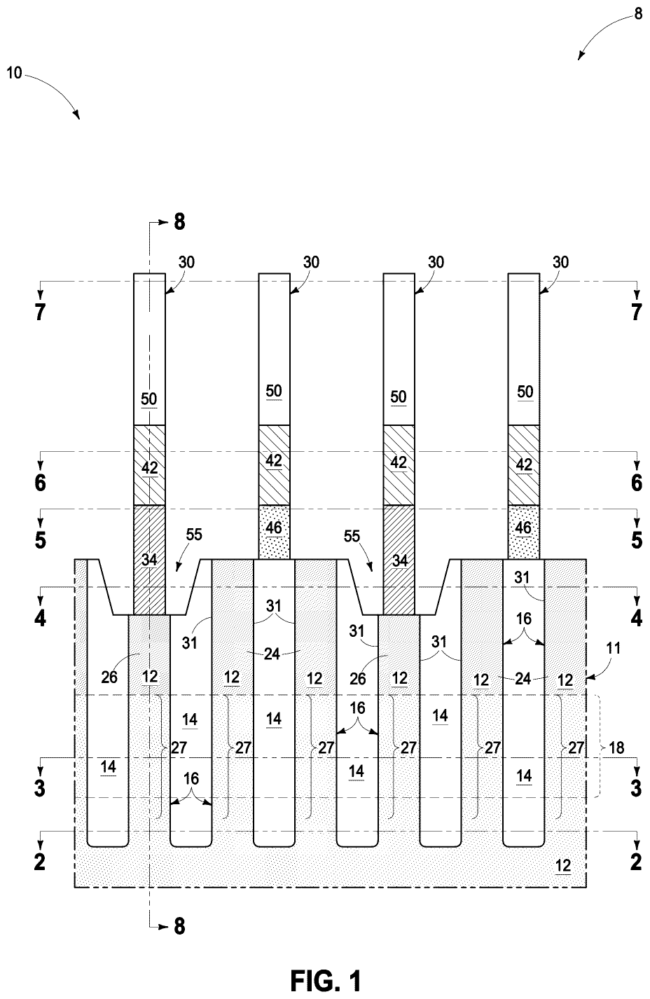

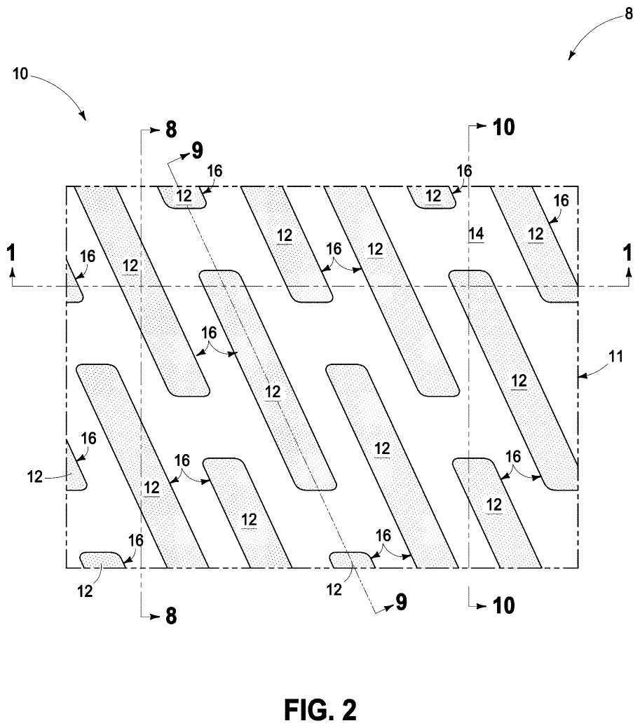

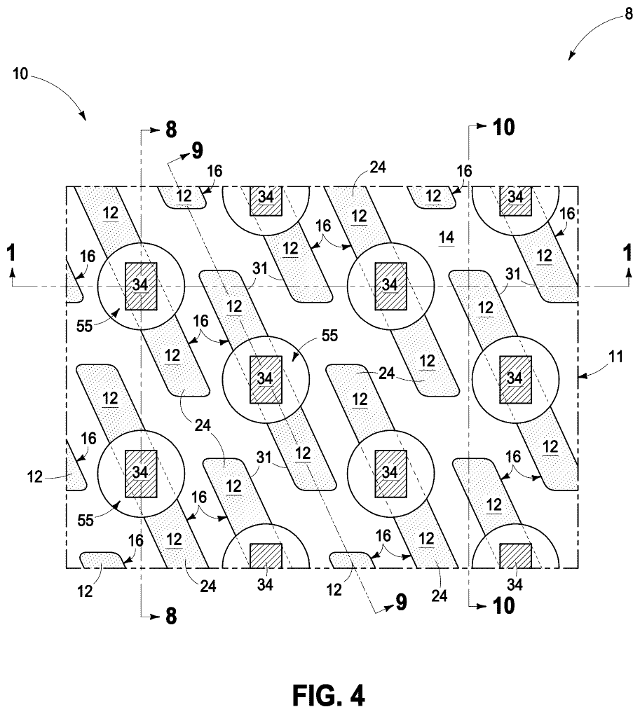

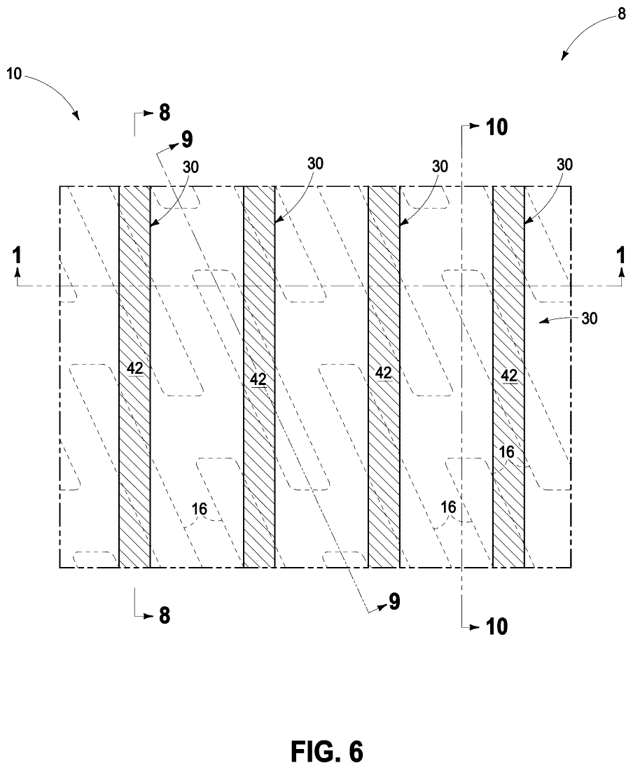

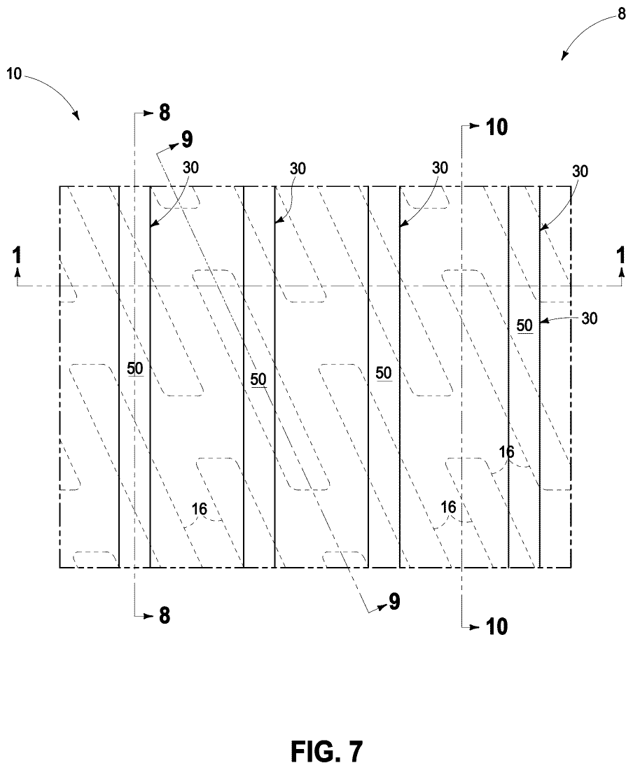

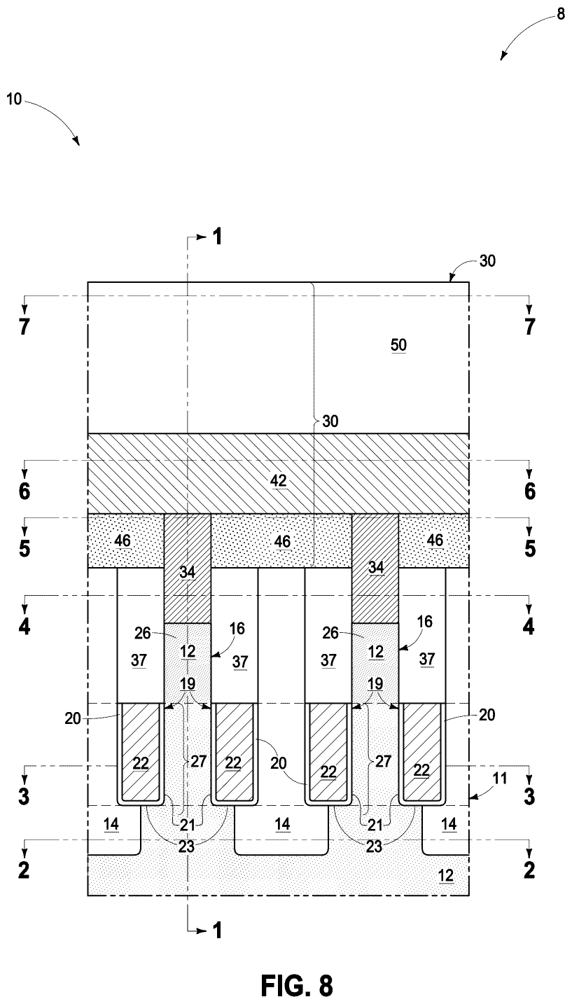

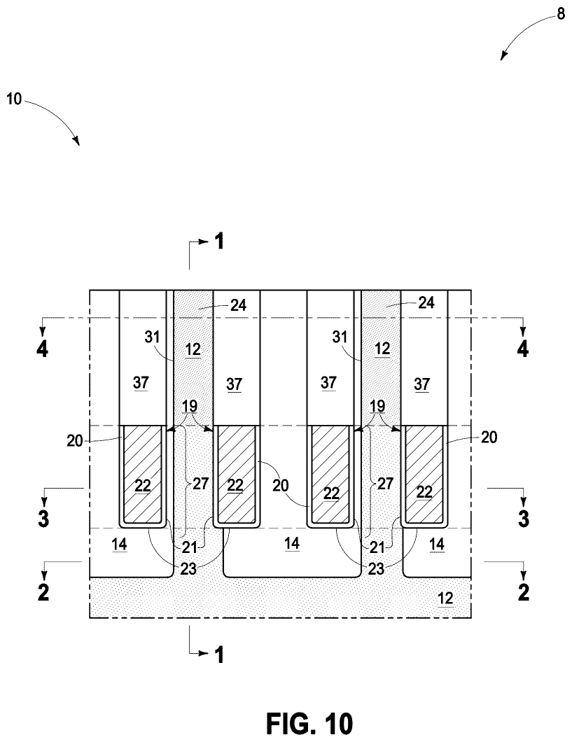

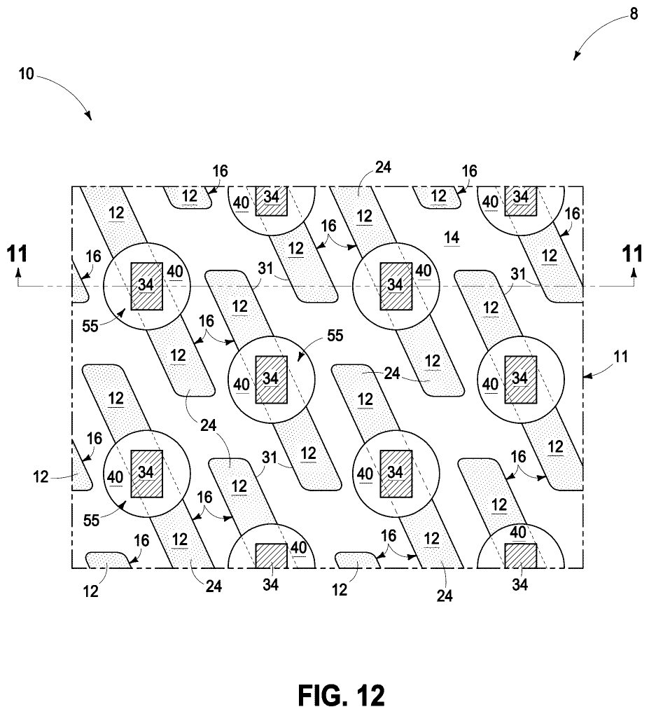

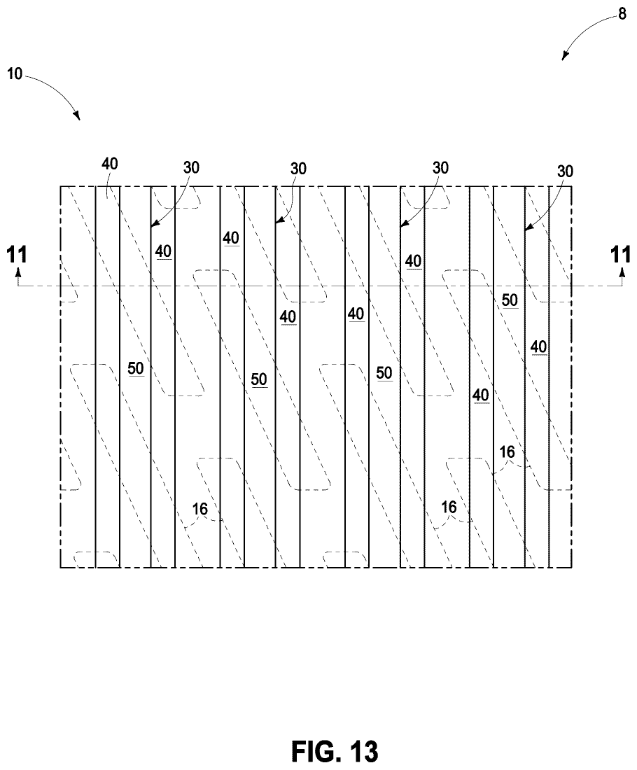

Embodiments of the invention encompass methods used in forming integrated circuitry, for example memory circuitry (e.g., DRAM). Example embodiments of methods of forming DRAM circuitry are described with reference to FIGS. 1-21. Referring to FIGS. 1-10, such show an example fragment of a substrate construction 8 comprising an array area 10 in the process of fabrication relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 1-10-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

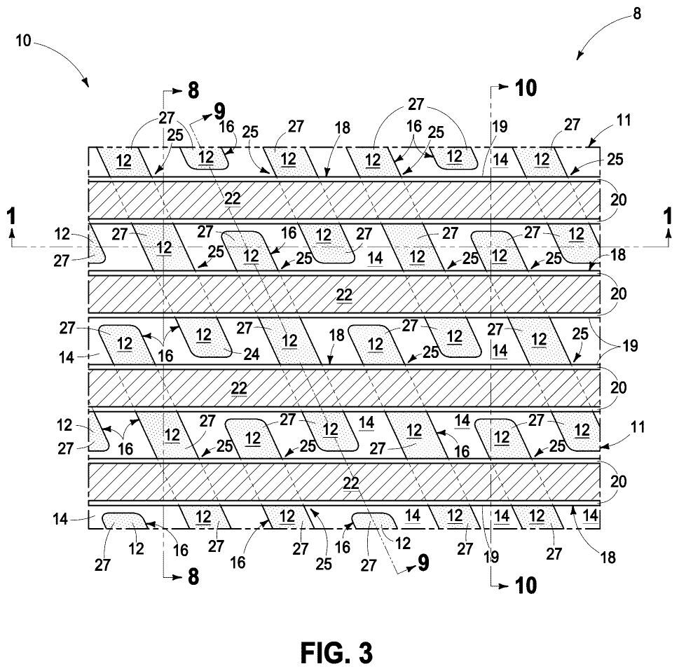

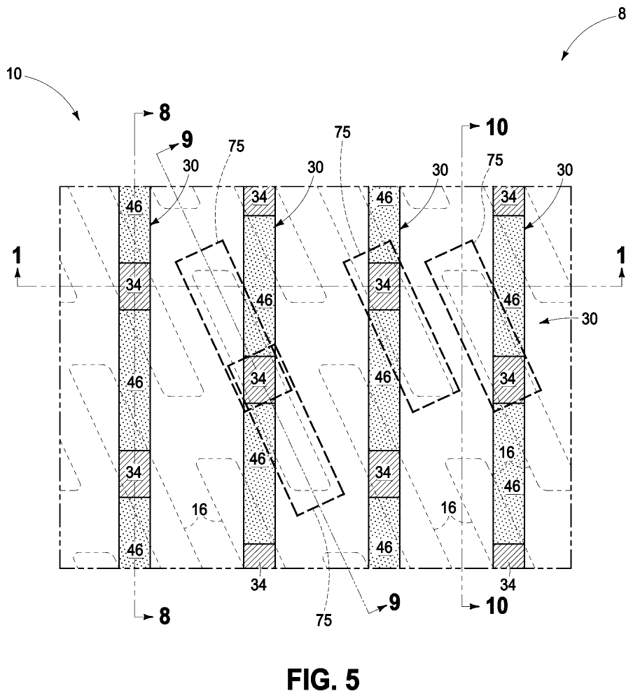

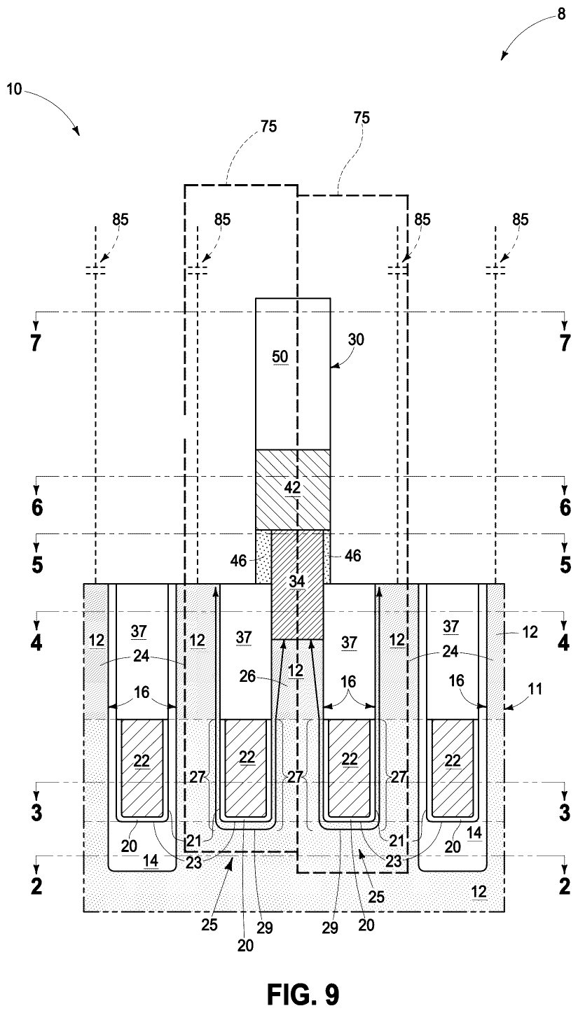

Base substrate 11 comprises semiconductive material 12 (e.g., appropriately and variously doped monocrystalline and/or polycrystalline silicon, Ge, SiGe, GaAs, and/or other existing or future-developed semiconductive material), trench isolation regions 14 (e.g., comprising insulating material 14 such as silicon nitride and/or silicon dioxide), and active area regions 16 comprising suitably and variously-doped semiconductive material 12. In one embodiment, construction 8 will comprise memory cells occupying space within outlines 75 (only two outlines 75 shown in FIG. 9 and only four outlines 75 shown in FIG. 5, for clarity in such figures), for example DRAM memory cells, individually comprising a field effect transistor device 25 (FIGS. 3 and 9) and a storage element 85 (e.g., a capacitor as described below). However, embodiments of the invention encompass fabricating of other memory cells.

Example transistor devices 25 individually comprise a pair of source/drain regions, a channel region between the pair of source/drain regions, a conductive gate operatively proximate the channel region, and a gate insulator between the conductive gate and the channel region. Devices 25 are shown as being recessed access devices, with example construction 8 showing such recessed access devices grouped in individual pairs of such devices. Individual recessed access devices 25 include a buried access line construction 18, for example that is within a trench 19 in semiconductive material 12 (e.g., extending along a row direction). Constructions 18 comprise conductive gate material 22 (e.g., conductively-doped semiconductor material and/or metal material, including for example elemental W, Ru, and/or Mo) that functions as a conductive gate of individual devices 25. A gate insulator 20 (e.g., silicon dioxide and/or silicon nitride) is along sidewalls 21 and a base 23 of individual trenches 19 between conductive gate material 22 and semiconductive material 12. Insulator material 37 (e.g., silicon dioxide and/or silicon nitride) is within trenches 19 above materials 20 and 22. Individual devices 25 comprise a pair of source/drain regions 24, 26 in upper portions of semiconductive material 12 on opposing sides of individual trenches 19 (e.g., regions 24, 26 being laterally outward of and higher than buried access line constructions 18). Each of source/drain regions 24, 26 has at least a part thereof having a conductivity-increasing dopant therein that is of maximum concentration of such conductivity-increasing dopant within the respective source/drain region 24, 26, for example to render such part to be conductive (e.g., having a maximum dopant concentration of at least 10¹⁸ atoms/cm³). Accordingly, all or only a part of each source/drain region 24, 26 may have such maximum concentration of conductivity-increasing dopant. Source/drain regions 24 and/or 26 may include other doped regions (not shown), for example halo regions, LDD regions, etc.

In the example embodiment, one of the source/drain regions (e.g., another source/drain region 26) of the pair of source/drain regions in individual of the pairs of transistors 25 is laterally between conductive gates 22 and is shared by the pair of devices 25. Others of the source/drain regions (e.g., one source/drain region 24) of the pair of source/drain regions are not shared by the pair of transistors 25. Thus, in the example embodiment, each active area region 16 comprises two transistors 25 (e.g., one pair of transistors 25), with each sharing a central source/drain region 26.

An example channel region 27 is in semiconductive material 12 below pair of source/drain regions 24, 26 along trench sidewalls 21 and around trench base 23. Channel region 27 may be undoped or may be suitably doped with a conductivity-increasing dopant likely of the opposite conductivity-type of the dopant in source/drain regions 24, 26. When suitable voltage is applied to gate material 22 of an access line construction 18, a conductive channel forms (e.g., along a channel current-flow line/path 29 [FIG. 9]) within channel region 27 proximate gate insulator 20 such that current is capable of flowing between a pair of source/drain regions 24 and 26 under the access line construction 18 within an individual active area region 16. Stippling is diagrammatically shown to indicate primary conductivity-modifying dopant concentration (regardless of type), with denser stippling indicating greater dopant concentration and lighter stippling indicating lower dopant concentration. Conductivity-modifying dopant may be, and would likely be, in other portions of material 12 as shown. Only two different stippling densities are shown in material 12 for convenience, and additional dopant concentrations may be used, and constant dopant concentration is not required in any region.

Conductive vias 34 have been formed and that are individually directly above and electrically coupled to individual of another source/drain regions 26. Individual of conductive vias 34 are in a cavity 55 that is in insulating material 14 that is laterally over sides 31 of one source/drain regions 24 of multiple of transistors 25.

Digitline structures 30 have been formed and that individually are directly electrically coupled to a plurality of conductive vias 34 along a line of a plurality of transistors 25 (e.g., in a column direction). Digitline structures 30 comprise conductive material 42, with conductive vias 34 extending downwardly from conductive material 42. Conductive vias 34 individually directly electrically couple digitline structures 30 to individual of shared source/drain regions 26 of the individual pairs of devices 25. Doped or undoped semiconductor material 46 may be between immediately-longitudinally-adjacent conductive vias 34. As alternate examples, material 46 may comprise insulative material(s) or metal material(s) or be eliminated, with conductive material 42 extending inwardly to insulating material 14 (not shown). Example digitline structures 30 comprise an insulator-material cap 50 (e.g., silicon nitride).

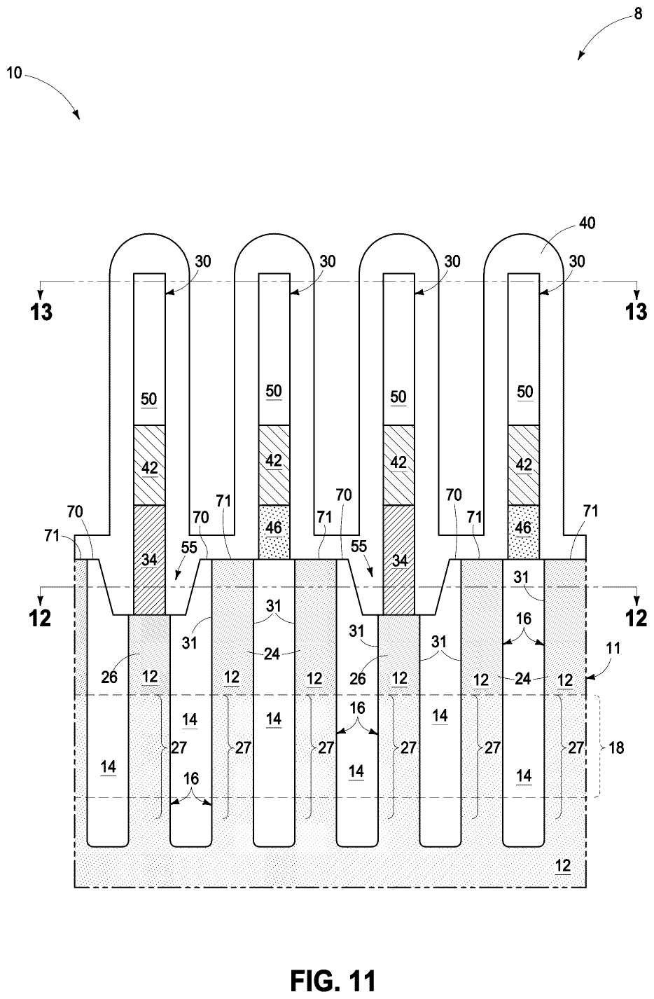

Referring to FIGS. 11-13, insulative material 40 has been formed in cavity 55 circumferentially around individual conductive vias 34. Insulative material 40 comprises SiOₓC_{y}, where “x” is 0.46 to 1.8 (ideally 1.2 to 1.6) and “y” is 0.01 to 1.1 (ideally 0.02 to 0.6), with the SiOₓC_{y} extending upwardly out of cavities 55 to be directly above respective uppermost surfaces 70 and 71 of insulating material 14 and one source/drain regions 24. Cavities 55 may be lined with one or more other materials (e.g., insulative, semiconductive, and/or conductive, and not shown). Regardless, and in some embodiments, at least a majority (i.e., above 50% by volume up to and including 100% by volume, herein) of insulative material 40 in cavity 55 is the SiOₓC_{y}, the SiOₓC_{y} is directly against conductive material of the conductive via, and insulative material 40 and insulating material 14 are of different compositions relative one another.

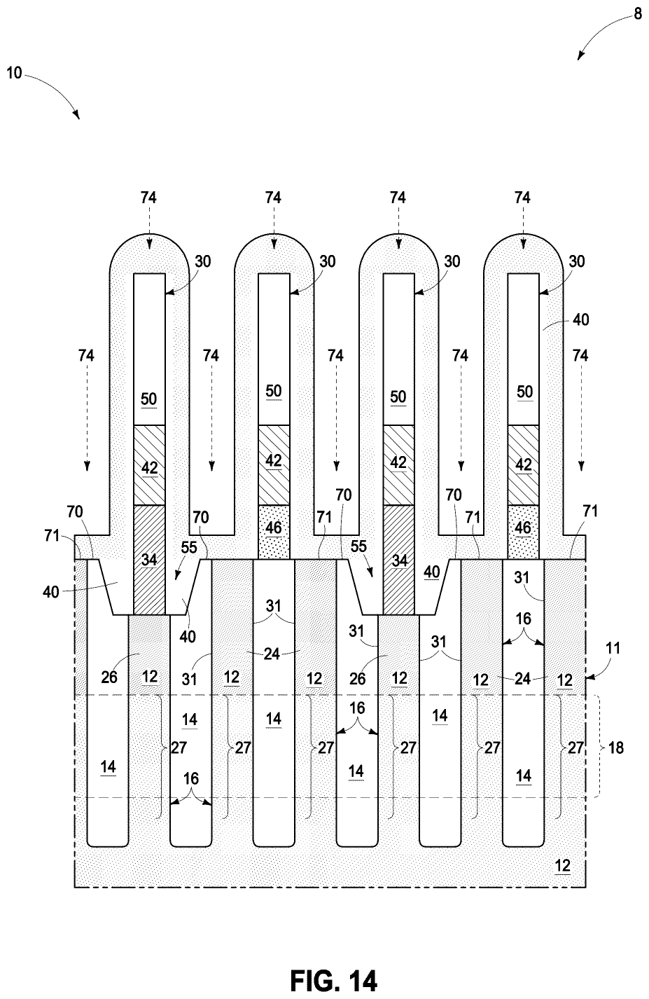

Referring to FIG. 14, an uppermost portion (at least) of the SiOₓC_{y} has been treated to remove carbon (some or all) therefrom (e.g., those portions that have been treated being indicated with stippling of insulative material 40). The treating removes sufficient carbon from insulative material 40 to change etch rate of the treated vs. the untreated insulative material 40 so that the treated portion can be etched selectively relative to the untreated portion in some selected etching chemistry. Ideally, such treating is with a downwardly-directional oxygen-containing plasma (e.g., indicated with downwardly directed arrows 74). For example, and by way of example only, such treating may be with O₂ and/or O₃, temperature of 40° C. to 80° C., pressure of 5 mTorr to 10 mTorr, bias of 400 Volts, and treating time from 2 seconds to 60 seconds. In one embodiment, the treating treats all of the SiOₓC_{y} that is directly above respective uppermost surfaces 70 and 71 of insulating material 14 and one source/drain regions 24 (as indicated by stippling in insulative material 40; e.g., leaving some of the SiOₓC_{y} that is closest alongside digitline structures 30 untreated).

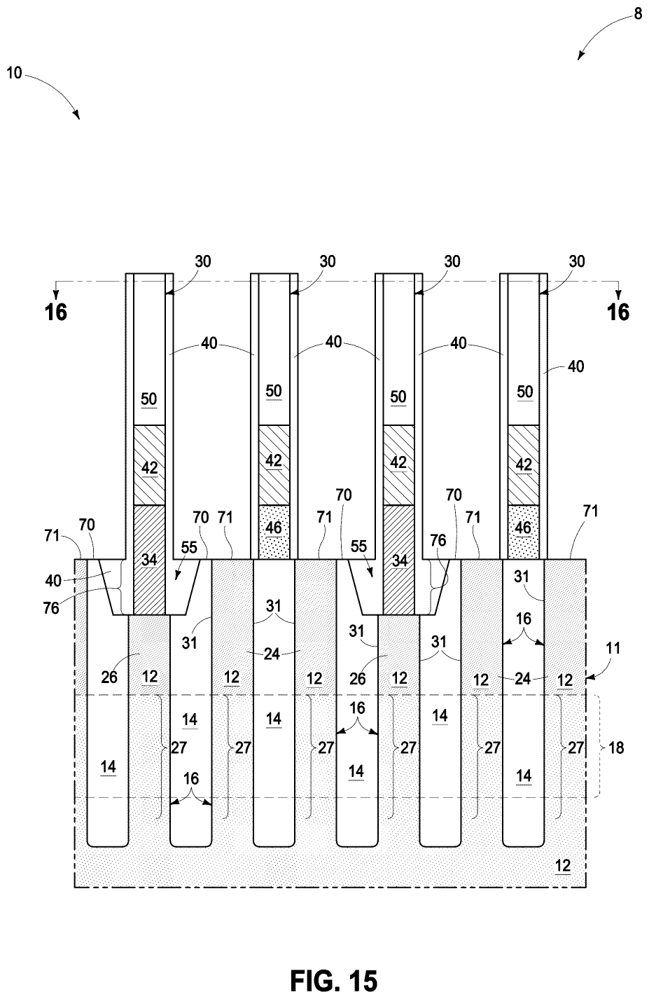

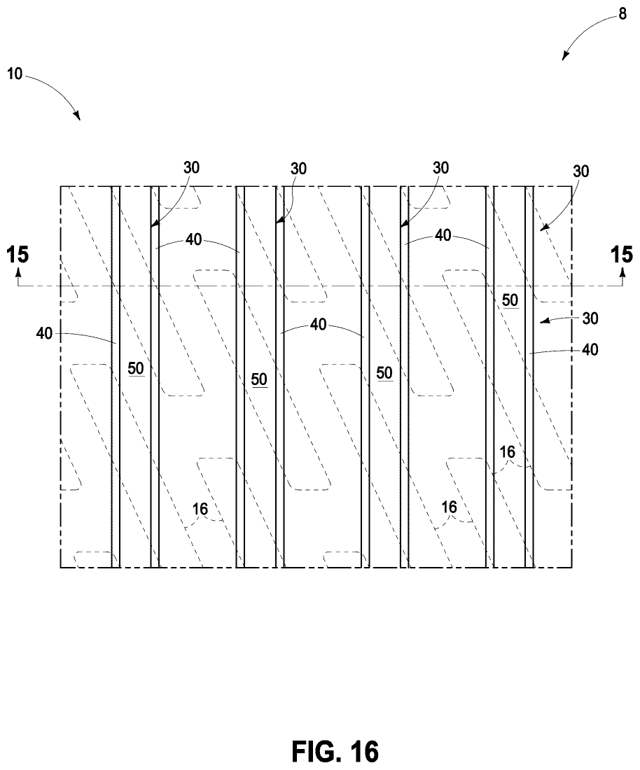

Referring to FIGS. 15 and 16, the treated uppermost portion of the SiOₓC_{y} (no longer shown) has been etched selectively relative to a lowest portion 76 (e.g., and any other untreated portion[s]) of the SiOₓC_{y} that is directly below the uppermost portion and has not been so treated). Ideally and as shown, some portion of the SiOₓC_{y} is untreated along sidewalls of digitline structures 30 and there remains.

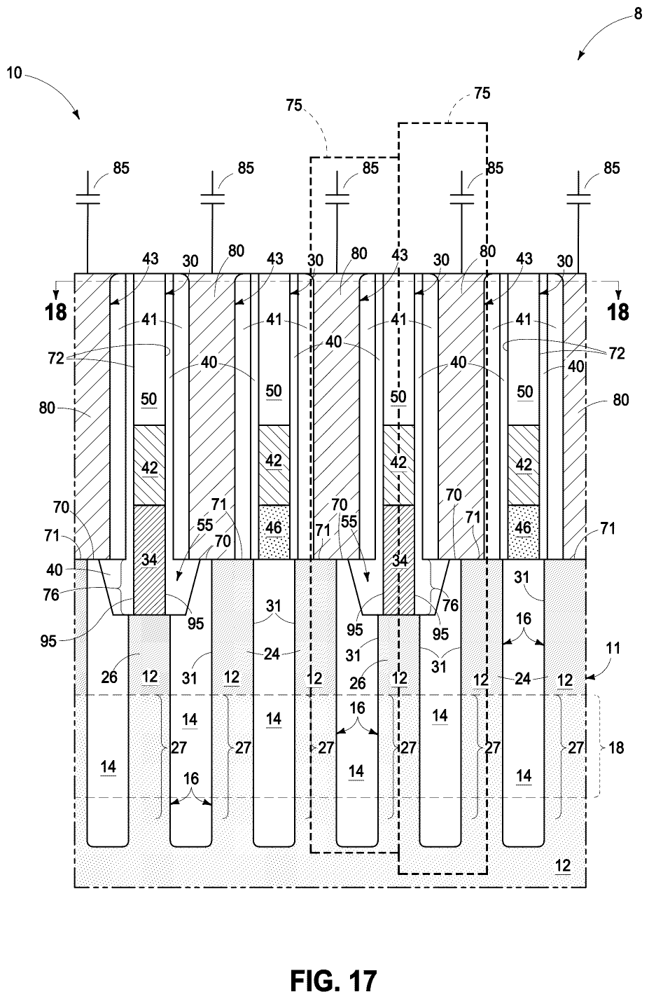

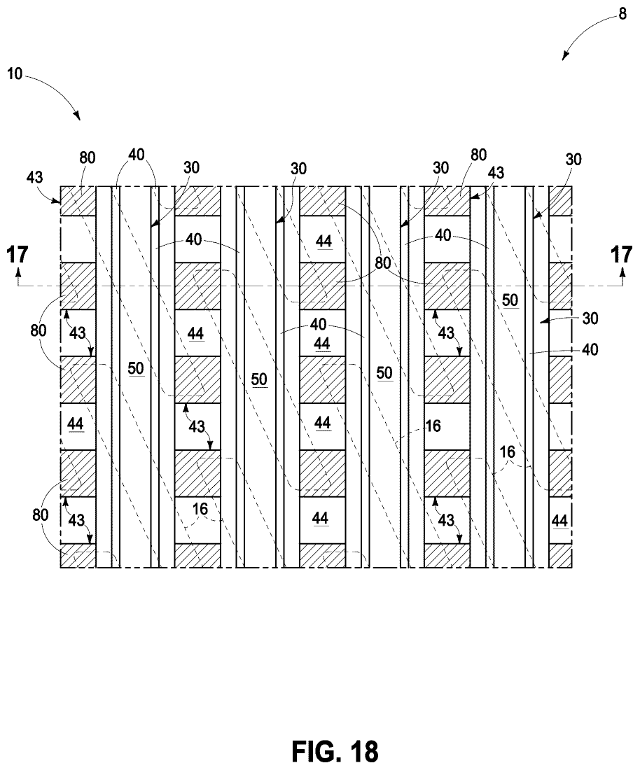

Storage elements are ultimately formed that are individually electrically coupled to individual of the one source/drain regions. One example method and structure are shown and described with reference to FIGS. 17 and 18, and by way of example only. Anisotropically-etched insulative sidewall spacers 41 (e.g., silicon nitride and/or silicon dioxide) have been formed aside or as part of digitline structures 30. Thereafter, insulative material 44 (e.g., silicon dioxide and/or silicon nitride) has been formed between digitline structures 30 and subsequently patterned to form contact openings 43 there-through to individual non-shared one source/drain regions 24. Conductive material 80 has subsequently been formed in contact openings 43 to directly electrically couple to individual one source/drain regions 24. Thereafter, storage elements 85 (e.g., capacitors) have been formed to directly electrically couple therewith.

Any other attribute(s) or aspect(s) as shown and/or described herein with respect to other embodiments may be used in the embodiments shown and described with reference to the above embodiments.

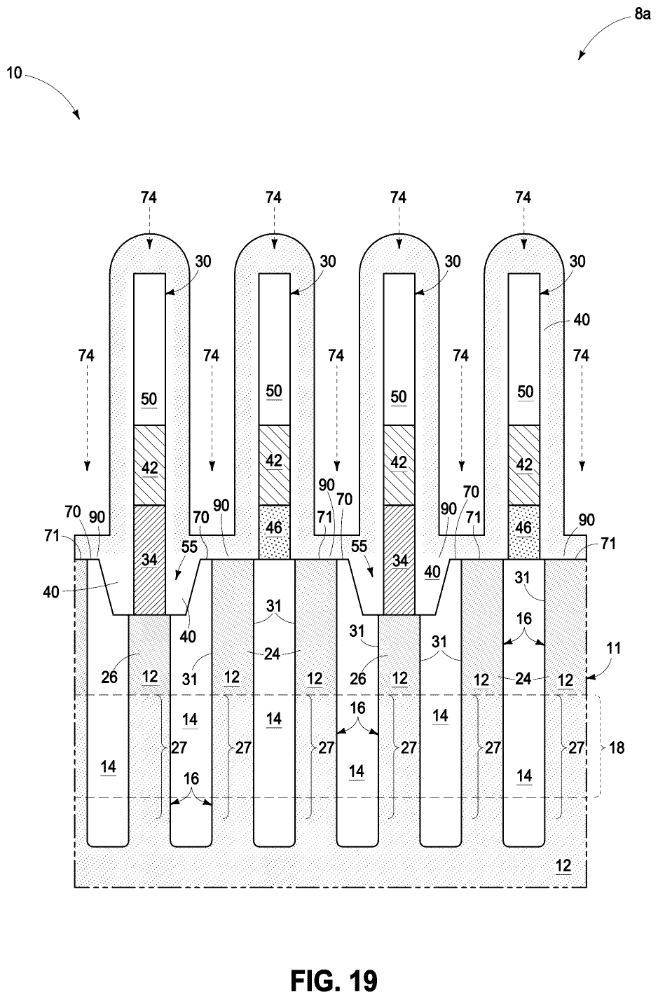

FIGS. 14-16 show all of the SiOₓC_{y} that is directly above the respective uppermost surfaces 70 and 71 of insulating material 14 and one source/drain regions 24 as having been treated, with the subsequent etching removing all and leaving none of the SiOₓC_{y} directly above such respective uppermost surfaces 70 and 71. FIGS. 19-21 show an alternate embodiment method and resultant construction 8a. Like numerals from the above-described embodiments have been used where appropriate, with some construction differences being indicated with the suffix “a”.

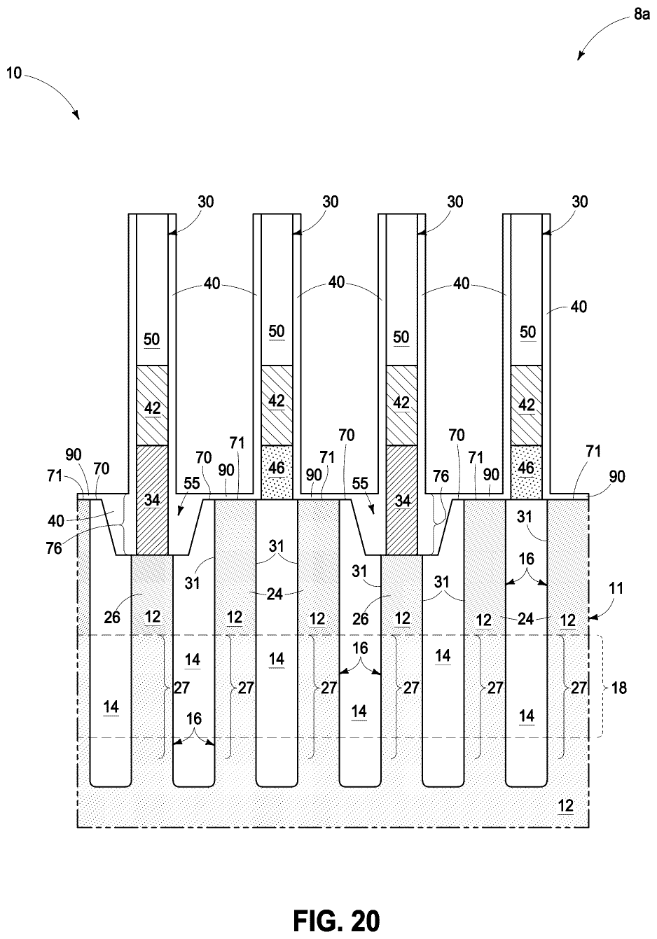

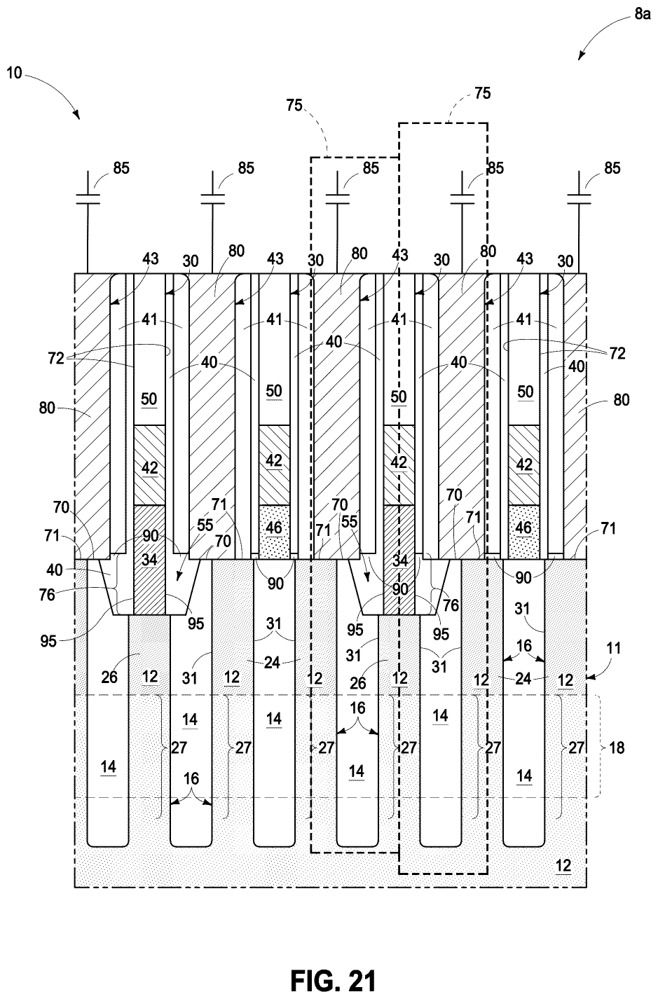

FIG. 19 is analogous to the processing shown by FIG. 14 but shows less-than-all of the SiOₓC_{y} that is directly above uppermost surfaces 70 and 71 as having been treated such that an untreated portion 90 (no stippling) is directly above uppermost surfaces 70 and 71. FIG. 20 is analogous to the processing shown by FIG. 15 but shows the etching leaving such untreated portion 90 directly above such respective uppermost surfaces 70 and 71 at the conclusion of such etching. FIG. 21 shows a finished-construction analogous to that shown by FIG. 17. Any other attribute(s) or aspect(s) as shown and/or described herein with respect to other embodiments may be used.

Method embodiments of the invention using SiOₓC_{y} as described above may provide an advantage of greater degree of filling of cavities 55 (e.g., with less, smaller, or no voids being formed therein that might otherwise lead to shorting or excessive leakage).

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, memory circuitry (e.g., 8, 8a) comprises transistors (e.g., 25) individually comprising one source/drain region (e.g., 24) and another source/drain region (e.g., 26). A channel region (e.g., 27) is between the one and the another source/drain regions. A conductive gate (e.g., 22) is operatively proximate the channel region. Conductive vias (e.g., 34) are individually directly above and electrically coupled (e.g., directly) to individual of the another source drain regions. Individual of the conductive vias are in a cavity (e.g., 55) that is in insulating material (e.g., 14) that is laterally over sides (e.g., 31) of the one source/drain regions of multiple of the transistors. Insulative material (e.g., 40) is in the cavity circumferentially around the individual conductive via. The insulative material comprises SiOₓC_{y}, where “x” is 0.46 to 1.8 and “y” is 0.01 to 1.1. At least a majority of the insulative material in the cavity is the SiOₓC_{y}. Digitlines (e.g., 30) are individually directly electrically coupled to a plurality of the conductive vias along a line of a plurality of the transistors. Storage elements (e.g., 85) are individually electrically coupled to individual of the one source/drain regions.

Further, in some ideal embodiments, at least a majority of insulative material 40 in cavity 55 is the SiOₓC_{y}, the SiOₓC_{y}, is along sidewalls 72 of digitline structures 30 (e.g., directly against conductive material 42 thereof), and the SiOₓC_{y} does not extend upwardly out of cavities 55 to be directly above respective uppermost surfaces 70 and 71 of insulating material 14 and one source/drain regions 24. Yet, in one embodiment (e.g., 8a), the SiOₓC_{y} extends upward out of the cavities to be directly above respective uppermost surfaces 70 and 71 and in one such embodiment is directly against respective uppermost surfaces 70 and 71.

Any other attribute(s) or aspect(s) as shown and/or described herein with respect to other embodiments may be used.

In one embodiment, memory circuitry (e.g., 8, 8a) comprises transistors (e.g., 25) individually comprising one source/drain region (e.g., 24) and another source/drain region (e.g., 26). A channel region (e.g., 27) is between the one and the another source/drain regions. A conductive gate (e.g., 22) is operatively proximate the channel region. Conductive vias (e.g., 34) are individually directly above and electrically coupled (e.g., directly) to individual of the another source drain regions. Individual of the conductive vias are in a cavity (e.g., 55) that is in insulating material (e.g., 14) that is laterally over sides (e.g., 31) of the one source/drain regions of multiple of the transistors. Insulative material (e.g., 40) is in the cavity circumferentially around the individual conductive via. The insulative material comprises SiOₓC_{y}, where “x” is 0.46 to 1.8 and “y” is 0.01 to 1.1. The SiOₓC_{y} is directly against sidewalls (e.g., 95) of the individual conductive via along at least a majority of height (e.g., as shown by brackets 76) of the conductive via within the cavity. Digitlines (e.g., 30) are individually directly electrically coupled to a plurality of the conductive vias along a line of a plurality of the transistors. Storage elements (e.g., 85) are individually electrically coupled to individual of the one source/drain regions.

In one such embodiment and as shown, the SiOₓC_{y} is directly against the sidewalls of the conductive via along all of the height of the conductive via within the cavity. In one such latter embodiment and as shown, the conductive via extends upwardly to be directly above the cavity, with the SiOₓC_{y} being directly against sidewalls of the conductive via along all of the conductive via that is directly above the cavity.

Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 450 from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming transistors individually comprising one source/drain region and another source/drain region. A channel region is between the one and the another source/drain regions. A conductive gate is operatively proximate the channel region. Conductive vias are formed that are individually directly above and electrically coupled to individual of the another source/drain regions. Individual of the conductive vias are in a cavity that is in insulating material that is laterally over sides of the one source/drain regions of multiple of the transistors. Digitlines are formed that are individually directly electrically coupled to a plurality of the conductive vias along a line of a plurality of the transistors. Insulative material is formed in the cavity that is circumferentially around the individual conductive via. The insulative material comprises SiOₓC_{y}, where “x” is 0.46 to 1.8 and “y” is 0.01 to 1.1. The SiOₓC_{y} extends upwardly out of the cavities to be directly above respective uppermost surfaces of the insulating material and the one source/drain regions. An uppermost portion of the SiOₓC_{y} is treated to remove carbon therefrom. After the treating, the treated uppermost portion of the SiOₓC_{y} is etched selectively relative to a lowest portion of the SiOₓC_{y} that is directly below the uppermost portion and has not been so treated. Storage elements are formed that are individually electrically coupled to individual of the one source/drain regions.

In some embodiments, memory circuitry comprises transistors individually comprising one source/drain region and another source/drain region. A channel region is between the one and the another source/drain regions. A conductive gate is operatively proximate the channel region. Conductive vias are individually directly above and electrically coupled to individual of the another source drain regions. Individual of the conductive vias are in a cavity that is in insulating material that is laterally over sides of the one source/drain regions of multiple of the transistors. Insulative material is in the cavity that is circumferentially around the individual conductive via. The insulative material comprises SiOₓC_{y}, where “x” is 0.46 to 1.8 and “y” is 0.01 to 1.1. At least a majority of the insulative material in the cavity is the SiOₓC_{y}. Digitlines are individually directly electrically coupled to a plurality of the conductive vias along a line of a plurality of the transistors. Storage elements are individually electrically coupled to individual of the one source/drain regions.

In some embodiments, memory circuitry comprises transistors individually comprising one source/drain region and another source/drain region. A channel region is between the one and the another source/drain regions. A conductive gate is operatively proximate the channel region. Conductive vias are individually directly above and electrically coupled to individual of the another source drain regions. Individual of the conductive vias are in a cavity that is in insulating material that is laterally over sides of the one source/drain regions of multiple of the transistors. Insulative material is in the cavity that is circumferentially around the individual conductive via. The insulative material comprises SiOₓC_{y}, where “x” is 0.46 to 1.8 and “y” is 0.01 to 1.1. The SiOₓC_{y} is directly against sidewalls of the individual conductive via along at least a majority of height of the conductive via within the cavity. Digitlines are individually directly electrically coupled to a plurality of the conductive vias along a line of a plurality of the transistors. Storage elements are individually electrically coupled to individual of the one source/drain regions.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming transistors individually comprising:
one source/drain region and another source/drain region;
a channel region between the one and the another source/drain regions; and
a conductive gate operatively proximate the channel region;
forming conductive vias that are individually directly above and electrically coupled to individual of the another source/drain regions, individual of the conductive vias being in a cavity that is in insulating material that is laterally over sides of the one source/drain regions of multiple of the transistors;
forming digitlines that are individually directly electrically coupled to a plurality of the conductive vias along a line of a plurality of the transistors;
forming insulative material in the cavity that is circumferentially around the individual conductive via, the insulative material comprising SiOₓC_{y}, where “x” is 0.46 to 1.8 and “y” is 0.01 to 1.1, the SiOₓC_{y} extending upwardly out of the cavities to be directly above respective uppermost surfaces of the insulating material and the one source/drain regions;
treating an uppermost portion of the SiOₓC_{y} to remove carbon therefrom;
after the treating, etching the treated uppermost portion of the SiOₓC_{y} selectively relative to a lowest portion of the SiOₓC_{y} that is directly below the uppermost portion and has not been so treated; and
forming storage elements that are individually electrically coupled to individual of the one source/drain regions.

2. The method of claim 1 wherein the treating is with a downwardly-directional oxygen-containing plasma.

3. The method of claim 1 wherein the treating treats all of the SiOₓC_{y} that is directly above the respective uppermost surfaces of the insulating material and the one source/drain regions, the etching leaving none of the SiOₓC_{y} directly above such respective uppermost surfaces.

4. The method of claim 1 wherein the treating treats less-than-all of the SiOₓC_{y} that is directly above the respective uppermost surfaces of the insulating material and the one source/drain regions such that an untreated portion is directly above such respective uppermost surfaces, the etching leaving such untreated portion directly above such respective uppermost surfaces at conclusion of such etching.

5. The method of claim 1 wherein at least a majority of the insulative material in the cavity is the SiOₓC_{y}.

6. The method of claim 1 wherein the insulating and insulative materials are of different compositions relative one another.

7. The method of claim 1 wherein the SiOₓC_{y} is directly against conductive material of the conductive via.

8. Memory circuitry comprising:
transistors individually comprising:
one source/drain region and another source/drain region;
a channel region between the one and the another source/drain regions; and
a conductive gate operatively proximate the channel region;
conductive vias that are individually directly above and electrically coupled to individual of the another source drain regions, individual of the conductive vias being in a cavity that is in insulating material that is laterally over sides of the one source/drain regions of multiple of the transistors;
insulative material in the cavity that is circumferentially around the individual conductive via, the insulative material comprising SiOₓC_{y}, where “x” is 0.46 to 1.8 and “y” is 0.01 to 1.1, at least a majority of the insulative material in the cavity being the SiOₓC_{y};
digitlines that are individually directly electrically coupled to a plurality of the conductive vias along a line of a plurality of the transistors; and
storage elements that are individually electrically coupled to individual of the one source/drain regions.

9. The memory circuitry of claim 8 wherein the “x” is 1.2 to 1.6 and the “y” is 0.02 to 0.6.

10. The memory circuitry of claim 8 wherein the insulating and insulative materials are of different compositions relative one another.

11. The memory circuitry of claim 8 wherein the SiOₓC_{y} is directly against conductive material of the conductive via.

12. The memory circuitry of claim 8 wherein the SiOₓC_{y} is along sidewalls of the digitlines.

13. The memory circuitry of claim 12 wherein the SiOₓC_{y} is directly against conductive material of the digitlines.

14. The memory circuitry of claim 8 wherein the insulating material and the one source/drain regions have respective uppermost surfaces, the SiOₓC_{y} not extending upward out of the cavities to be directly above the respective uppermost surfaces.

15. The memory circuitry of claim 8 wherein the insulating material and the one source/drain regions have respective uppermost surfaces, the SiOₓC_{y} extending upward out of the cavities to be directly above the respective uppermost surfaces.

16. The memory circuitry of claim 15 wherein the SiOₓC_{y} is directly against the respective uppermost surfaces.

17. Memory circuitry comprising:
transistors individually comprising:
one source/drain region and another source/drain region;
a channel region between the one and the another source/drain regions; and
a conductive gate operatively proximate the channel region;
conductive vias that are individually directly above and electrically coupled to individual of the another source drain regions, individual of the conductive vias being in a cavity that is in insulating material that is laterally over sides of the one source/drain regions of multiple of the transistors;
insulative material in the cavity that is circumferentially around the individual conductive via, the insulative material comprising SiOₓC_{y}, where “x” is 0.46 to 1.8 and “y” is 0.01 to 1.1, the SiOₓC_{y} being directly against sidewalls of the individual conductive via along at least a majority of height of the conductive via within the cavity;
digitlines that are individually directly electrically coupled to a plurality of the conductive vias along a line of a plurality of the transistors; and
storage elements that are individually electrically coupled to individual of the one source/drain regions.

18. The memory circuitry of claim 17 wherein the SiOₓC_{y} is directly against the sidewalls of the conductive via along all of the height of the conductive via within the cavity.

19. The memory circuitry of claim 18 wherein the conductive via extends upwardly to be directly above the cavity, the SiOₓC_{y} being directly against sidewalls of the conductive via along all of the conductive via that is directly above the cavity.

20. The memory circuitry of claim 17 wherein the insulating and insulative materials are of different compositions relative one another.
